(19) United States
(12) Patent Application Publication
(10) Pub. No.: US 2025/0029840 A1
(43) Pub. Date: Jan. 23, 2025

(54) MOLYBDENUM DEPOSITION

(71) Applicant: Lam Research Corporation, Fremont, CA (US)

(72) Inventors: Patrick A. VAN CLEEMPUT, Castle Rock, WA (US); Shruti Vivek THOMBARE, Sunnyvale, CA (US); Michal DANEK, Cupertino, CA (US)

(21) Appl. No.: 18/907,394

(22) Filed: Oct. 4, 2024

Related U.S. Application Data
(63) Continuation of application No. 17/294,378, filed on May 14, 2021, now Pat. No. 12,148,623.
(60) Provisional application No. 62/769,479, filed on Nov. 19, 2018.

(51) Int. Cl. H01L 21/285; C23C 16/06; C23C 16/455; H01L 23/532; H10B 12/00; H10B 41/27; H10B 43/27

(52) U.S. Cl. CPC H01L 21/28568; C23C 16/06; C23C 16/45525; H01L 23/53257; H10B 12/34; H10B 41/27; H10B 43/27

(57) ABSTRACT

Provided herein are low resistance metallization stack structures for logic and memory applications and related methods of fabrication. The methods involve forming bulk conductive films on thin low resistivity transition metal layers that have large grain size. The bulk conductive films follow the grains of the low resistivity transition metal films, resulting in large grain size. Also provided are devices including template layers and bulk films.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

Tungsten (W) film deposition using chemical vapor deposition (CVD) techniques is an integral part of semiconductor fabrication processes. For example, tungsten films may be used as low resistivity electrical connections in the form of horizontal interconnects, vias between adjacent metal layers, and contacts between a first metal layer and the devices on a silicon substrate. Tungsten films may also be used in various memory applications, including in formation of buried wordline (bWL) architectures for dynamic random access memory (DRAM), word lines for 3D NAND, and logic applications. However, the continued decrease in feature size and film thickness brings various challenges including high resistivity for thinner films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of forming low resistivity bulk conductors. The methods involve forming bulk conductive films on thin low resistivity transition metal layers that have large grain size. The bulk conductive films follow the grains of the low resistivity transition metal films, resulting in large grain size. Also provided are devices including template layers and bulk films.

One aspect of the disclosure may be implemented in a method involving providing a molybdenum (Mo)-containing layer in a feature on a substrate; and depositing a tungsten (W)-containing layer on the Mo-containing layer to thereby fill the feature. In some embodiments, the method further includes annealing the Mo-containing layer prior to depositing the W-containing layer. The Mo-containing layer may be a template for W grain growth. In some embodiments, the Mo-containing layer is elemental Mo having less than 1 (atomic) % impurities. The Mo-containing layer may be relatively thin, for example, between 1 and 10 nm or 1 and 5 nm thick. The W-containing layer may be at least 5, 10, or 20 times thicker than the Mo-containing layer. In some embodiments, the Mo-containing layer overlies a dielectric layer, such as a silicon oxide or aluminum oxide layer. In some embodiments, the Mo-containing layer overlies a barrier layer, such as a titanium nitride layer. In some embodiments, the Mo-containing layer is free of fluorine impurities.

In some embodiments, the average crystallite size of the Mo-containing layer is at least 20 nm. In some embodiments, the average crystallite of the W-containing layer is at least 20 nm.

The method may further involve depositing the Mo-containing layer. In some embodiments, the Mo-containing layer is deposited from one or more molybdenum chloride precursors. Examples include molybdenum pentachloride (MoCl₅), molybdenum dichloride dioxide (MoO₂Cl₂), and molybdenum tetrachloride oxide (MoOCl₄). In some embodiments, the depositing the Mo-containing layer comprises performing an atomic layer deposition process in which a molybdenum chloride precursor is reduced by hydrogen.

In some embodiments, the W-containing layer is deposited using tungsten hexafluoride. The W-containing layer may be deposited without depositing a nucleation layer. In some embodiments, the W-containing layer is deposited by atomic layer deposition (ALD). In some embodiments, the tungsten-containing film is deposited by chemical vapor deposition (CVD).

Another aspect of the disclosure may be implemented in a method including forming a conductive template layer on a substrate, the template layer being between 1 and 5 nm; annealing the conductive template layer to increase grain size with the conductive template layer; and forming a bulk conductive layer on the template layer, wherein the grains in the bulk conductive layer follow that of the conductive template layer. In some embodiments, the conductive template layer is molybdenum. The bulk conductive layer may be selected from the group consisting of one of tungsten, cobalt, ruthenium, nickel, and alloys containing at least one of tungsten, cobalt, ruthenium, nickel. In some embodiments, the conductive template layer is deposited to line a feature and the bulk conductive layer is deposited to fill the feature with bulk conductive material.

Another aspect of the disclosure may be implemented in a method including providing a partially fabricated 3-D NAND structure having multiple oxide layers separated by gaps; and conformally depositing a molybdenum template layer in the gaps, the molybdenum template layer being between about 1 and 10 nm thick. In some embodiments, the molybdenum template layer is deposited directly on an oxide surface. In some embodiments, the molybdenum template layer is between 1 and 5 nm thick. The method may further include filling the gaps with tungsten.

Another aspect of the disclosure may be implemented in a method of filling a 3-D structure of a partially manufactured semiconductor substrate with tungsten, the 3-D structure comprising sidewalls, a plurality of openings in the sidewalls leading to a plurality of features having a plurality of interior regions fluidically accessible through the openings, the method involving depositing a first layer of molybdenum within the 3-D structure such that the first layer conformally lines the plurality of features of the 3-D structure; and depositing tungsten (W) on the Mo-containing layer to thereby fill the feature with tungsten.

Another aspect of the disclosure may be implemented in an apparatus that includes one or more chambers each configured to house a substrate; a support substrate in each of the one or more chambers; gas inlets configured to direct gas into each of the one or more chambers; a heater configured to heat the substrate support in each chamber; and a controller comprising program instructions for inletting a molybdenum precursor into the one or more chambers; and after inletting the molybdenum precursor, inletting a tungsten precursor into the one or more chambers.

Another aspect of the disclosure may be implemented in 3-D NAND structure that includes multiple tungsten wordlines separated by oxide layers; and a molybdenum thin film at the tungsten-oxide interface. In some embodiments, the molybdenum thin film is between 1 and 5 nm thick.

These and other aspects are discussed below with reference to the Figures.

### BRIEF DESCRIPTIONS OF DRAWINGS

FIGS. 1A and 1B are schematic examples of material stacks that include molybdenum (Mo) templates and tungsten (W) conductors according to various embodiments.

FIG. 2 depicts a schematic example of a DRAM architecture including a W buried wordline (bWL) on a Mo template.

FIG. 3A depicts a schematic example of a W wordline in a 3D NAND structure.

FIG. 3B depicts a material stack of a W wordline including a Mo template layer.

FIG. 4 is a process flow diagram illustrating operations in a method of depositing a conductive material.

FIG. 5 is a process flow diagram illustrating operations in a method of filling a feature with tungsten.

FIG. 6 shows an image of a tungsten film deposited on a molybdenum template.

FIG. 7 is a graph showing the reduction in resistivity for Mo films of various thicknesses after anneal at 800°° C.

FIG. 8 is a block diagram of a processing system suitable for conducting deposition processes in accordance with embodiments described herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

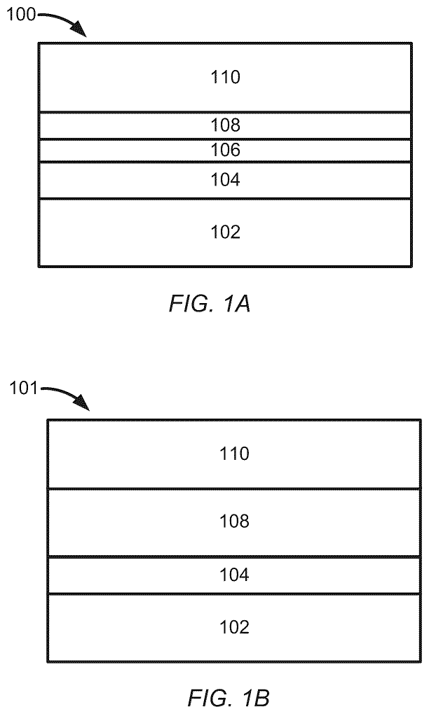

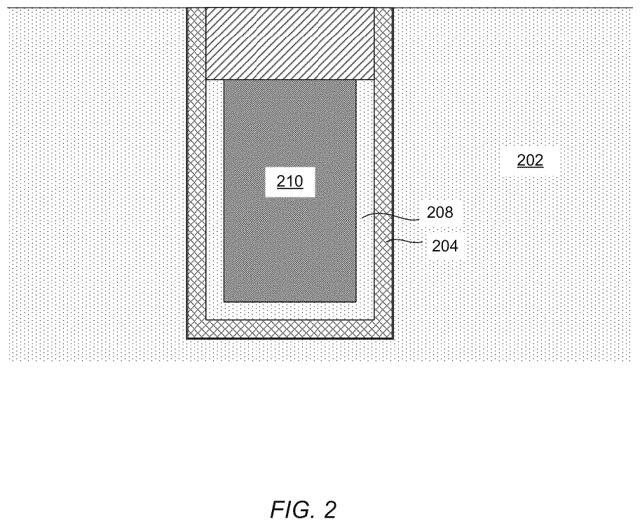

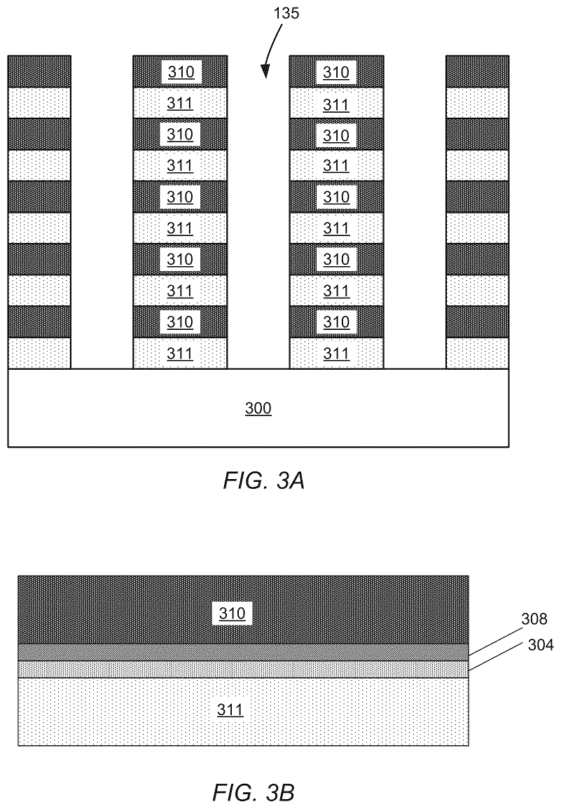

Provided herein are low resistance metallization stack structures for logic and memory applications. FIGS. 1A and 1B are schematic examples of material stacks that include molybdenum (Mo) as a template for tungsten growth. FIGS. 1A and 1B illustrate the order of materials in a particular stack and may be used with any appropriate architecture and application, as described further below with respect to FIGS. 2, 3A, and 3B. In the example of FIG. 1A, a substrate 102 has a Mo layer 108 is deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., Si) surface of the substrate 102, or there may be any number of intervening layers. Examples of dielectric layers include doped and undoped silicon oxide, silicon nitride, and aluminum oxide layers, with specific examples including doped or undoped layers SiO₂ and Al₂O₃. Also, in FIG. 1A, a diffusion barrier layer 106 is disposed between the Mo layer 108 and the dielectric layer 104. Examples of diffusion barrier layers including titanium nitride (TiN), titanium/titanium nitride (Ti/TiN), tungsten nitride (WN), and tungsten carbon nitride (WCN). Further examples diffusion barriers are multi-component Mo-containing films as described further below. A tungsten (W) layer 110 is deposited on the Mo layer 108 and is the main conductor of the structure. As discussed further below, the Mo layer 108 provides a template for tungsten growth. As a result, in some embodiments, the W layer 110 is deposited without a tungsten nucleation layer.

FIG. 1B shows another example of a material stack. In this example, the stack includes the substrate 102, dielectric layer 104, with Mo layer 108 deposited directly on the dielectric layer 104, without an intervening diffusion barrier layer. As in the example of FIG. 1A, a W layer 110 is deposited on the Mo layer 108 and is the main conductor of the structure. By using molybdenum, which has large grains, as a template for tungsten growth, tungsten having large grains and low resistivity can be formed. Further, resistivity can be improved by eliminating the higher resistivity tungsten nucleation layer.

While FIGS. 1A and 1B show examples of metallization stacks, the methods and resulting stacks are not so limited. For example, in some embodiments, Mo may be deposited directly on a Si or other semiconductor substrate as a template for tungsten growth.

Further, while W growth on Mo templates is described in the examples above, the Mo layer may serve as a template for low resistivity growth of other metals including molybdenum (Mo), cobalt (Co), ruthenium (Ru), nickel (Ni), and alloys including these metals such as MoW.

The material stacks described above and further below may be employed in a variety of embodiments. FIGS. 2, 3A, and 3B provide examples of structures in which the stacks may be employed. FIG. 2 depicts a schematic example of a DRAM architecture including a W buried wordline (bWL) 210 in a silicon substrate 202. The W bWL 210 is formed in a trench etched in the silicon substrate 202. Lining the trench is a conformal Mo layer 208 and an insulating layer 204 that is disposed between the conformal barrier layer 206 and the silicon substrate 202. In the example of FIG. 2, the insulating layer 204 may be a gate oxide layer, formed from a high-k dielectric material such as a silicon oxide or silicon nitride material. In some embodiments, a conformal barrier layer such as TiN or a tungsten-containing layer may be interposed between the Mo layer 208 and the insulating layer 204.

FIG. 3A depicts a schematic example W wordlines 310 in a 3D NAND structure 323. The W wordlines 310 are separated by oxide layers 311. In FIG. 3B, a detail of the interface between a W wordline 310 and oxide layer 311 is shown including a layer of aluminum oxide (Al₂O₃) 304 and a Mo layer 308 is shown. As described above, the W wordlines 310 may be deposited on the Mo layers 308 without a tungsten nucleation layer. In some embodiments, the Mo layer 308 may be deposited directly on the oxide layer 311 or on a TiN or other barrier layer as described herein. The Mo layers may be between about 10 Å and 100 Å, or 10 Å and 50 Å, for example, for deposition of a W wordline layer of between about 10 nm and 100 nm.

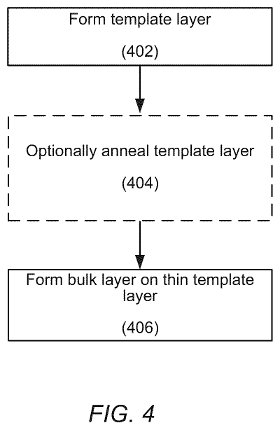

FIG. 4 is a process flow diagram illustrating operations in a method of depositing a conductive material. In operation 402, a template layer is formed. As described further below, this can involve vapor deposition techniques such as chemical vapor deposition (CVD) and atomic layer deposition (ALD) deposition. The template layer is a material that has relatively large grain growth such as molybdenum. The layer may be relatively thin, no more than 10 nm or no more than 50 nm in some embodiments. Generally, the layer is thick enough for continuous growth on the underlying structure. Example thicknesses range from 1 nm-5 nm, or 2 nm to 5 nm. The template layer may conform to the underlying structure as in the examples of FIGS. 2 and 3B. For challenging structures, such as 3D NAND structures, ALD may be used to form a conformal layer. Example surfaces on which the template layer may be formed include dielectric and barrier layer surfaces. In certain embodiments, the template layer may be deposited from a non-fluorine-containing precursor. This can prevent fluorine from migrating to the underlying structure.

In some embodiments, the template layer is annealed in an operation 402. Thermal anneal of a layer can increase grain size and lower resistivity. Examples of anneal temperatures for molybdenum range from 700° C. to 1100° C. In general, the anneal is performed at temperatures at or near the melting temperature. The anneal may be performed in a furnace or by rapid thermal annealing. According to various embodiments, it may be performed in any appropriate ambient, including a hydrogen (H₂) ambient, a nitrogen (N₂) ambient, or vacuum. In some embodiments, the film may be exposed to a reducing environment prior to anneal to remove any oxide formation. Oxides may form in particular if the template is exposed to air prior to anneal. At operation 406, a bulk layer is formed on the template layer. Grain size is larger as a result of being deposited on the template. The bulk layer is generally the main conductor of the structure. By depositing it on a template, less expensive and/or readily available precursors such as tungsten hexafluoride (WF₆) or molybdenum hexafluoride (MoF₆) may be used. ALD or CVD methods may be used, depending on the structure. In one example, WF₆ and H₂ are used to deposit tungsten. Deposition of other bulk films is described further below.

Methods of forming Mo template layers include vapor deposition techniques such as (CVD and ALD deposition. In an ALD technique, pulses of a reducing agent (or other co-reactant), optional purge gases, and Mo-containing precursor are sequentially injected into and purged from the reaction chamber. Deposition of the Mo layer can alternatively occur by a CVD process in which a reducing agent and a Mo-containing precursor are flowed into a deposition chamber to deposit a Mo layer in the feature. An inert carrier gas may be used to deliver one or more of the reactant streams, which may or may not be pre-mixed. Unlike ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

Mo-containing precursors include molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆). Organometallic precursors such as molybdenum silylcyclopentadienyl and molybdenum silylallyl complexes may be used. Mo-containing precursors may be halide precursors, which include MoF₆ and MoCl₅ as well as mixed halide precursors that have two or more halogens that can form a stable molecule. An example of a mixed halide precursor is MoClₓBr_{y} with x and y being any number greater than 0 that can form a stable molecule

In certain embodiments, a Mo layer is deposited directly on a dielectric layer or on a TiN or other barrier layer. In an ALD process, pulses of a co-reactant, optional purge gases, and Mo-containing precursor are sequentially injected into and purged from the reaction chamber. In some embodiments, a thin Mo layer deposited using one or more of a boron-containing reducing agent (e.g., B₂H₆), a silicon-containing reducing agent (e.g., SiH₄), or hydrogen (H₂) as a co-reactant. For example, one or more S/Mo cycles, where S/Mo refers to a pulse of silane followed by a pulse of a Mo-containing precursor, may be employed to deposit a thin Mo layer that will serve as a template for tungsten deposition. In another example, one or more B/Mo cycles, where B/Mo refers to a pulse of diborane followed by a pulse of a Mo-containing precursor, may be employed to deposit a thin Mo layer on which a tungsten layer is to be deposited. B/Mo and S/Mo cycles may both be used to deposit a Mo layer, e.g., x(B/Mo)+y(S/Mo), with x and y being integers. Still further one or more H₂/Mo cycles may be used to deposit a thin Mo layer, with or without B/Mo and/or S/Mo cycles.

Depending on the thickness of the Mo layer and the structure on which it is to be deposited, depositing the Mo layer can involve deposition of a Mo nucleation layer followed by deposition by a bulk layer. In some embodiments, this can involve ALD deposition of the nucleation layer followed by CVD deposition of the bulk layer.

In some embodiments, deposition of the Mo template layer can involve forming a reducing agent layer followed by exposure of the reducing agent layer to a Mo-containing precursor. A reducing agent layer may include or consist essentially of elemental silicon (Si), elemental boron (B), elemental germanium (Ge), or mixtures thereof. For example, a reducing agent layer may include Si and B. The amount of B may be tailored to achieve high deposition rate of the reducing agent layer but with low resistivity.

Substrate temperature during Mo deposition may be between 300° C. to 800° C. Substrate temperature will depend on the thermal budget and the deposition chemistry. Thermal budget depends on the applications, while high deposition temperature may not be an issue for memory applications, it can exceed the thermal budget for logic applications.

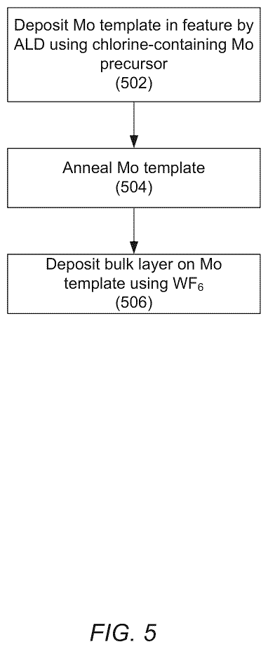

FIG. 5 shows an example of a process for feature fill. The process in FIG. 5 may be used for tungsten wordline fill, for example. In an operation 502, a Mo template is deposited by ALD using a chlorine-containing Mo precursor. The ALD process may be used to achieve conformality and step coverage over challenging 3D NAND structures. The ALD cycles may be used to deposit a Mo layer between about 10 Å and 50 Å, for example, on a dielectric or barrier layer surface. In some embodiments, the ALD cycles use H₂ as the reducing agent, without having boron or silicon incorporated into the film. Further, the ALD cycle use chloride-containing precursors. This prevents the underlying dielectric layer from being exposed to fluorine. For chlorine containing Mo precursors, relatively high deposition temperature may be used, e.g. 450° C.-800° C., and in some embodiments, at least 500°, or between 550° C. and 650° C. Because the Mo—Cl bond in these precursors is relatively strong, high temperatures facilitate deposition.

Then, in an operation 504, the Mo template is annealed. As described above, the annealing may be preceded by a reducing step to remove any oxide. This can remove molybdenum dioxide (MoO₂) or molybdenum trioxide (MoO₃) that has formed as a result of air or other oxidant exposure. MoO₃ in particular has a melting point of 795° C. and could melt during anneal if not removed. A bulk layer is then deposited on the Mo template to form the wordline or other conductor in an operation 506. The tungsten fill can involve a fluorinated precursor such as WF₆, with the Mo layer providing a barrier against fluorine migration to the dielectric. For 3D NAND structures, operation 506 may involve alternating pulses of WF₆ and H₂ in an ALD deposition. The deposition may be performed without forming a tungsten nucleation layer in some embodiments. Example thicknesses for tungsten range between 50 Å and 300 Å. The ratio of W:Mo thickness may be 1:1-15:1 according to some embodiments, e.g., 2:1-10:1, or 2:1-5:1.

As described above, the method discussed with reference to FIG. 4 may be used to deposit other low resistivity bulk films on templates. Such films can include cobalt (Co), ruthenium (Ru), and nickel (Ni). Examples of cobalt precursors dicarbonyl cyclopentadienyl cobalt, cobalt carbonyl, a cobalt amidinate precursor, a cobalt diazadienyl complex, and a cobalt amidinate/guanidinate precursor. Examples of ruthenium precursors that may be used for oxidative reactions include (ethylbenzyl)(1-ethyl-1,4-cyclohexadienyl)Ru(0), (1-isopropyl-4-methylbenzyl)(1,3-cyclohexadienyl)Ru(0), 2,3-dimethyl-1,3-and butadienyl)Ru(0) tricarbonyl, (1,3-cyclohexadienyl)Ru(0)tricarbonyl, (cyclopentadienyl)(ethyl)Ru(II) dicarbonyl. Examples of ruthenium precursors that react with non-oxidizing reactants are bis (5-methyl-2,4-hexanediketonato)Ru(II)dicarbonyl and bis(ethylcyclopentadienyl)Ru(II). Examples of nickel precursors include cyclopentadienylallylnickel (CpAllylNi) and MeCp₂Ni.

In the description above, ALD may be used to deposit the bulk tungsten or other bulk material. In particular, ALD may be used to deposit tungsten or other metal that has lateral grain growth. In this manner, the deposited metal has much larger grain growth, including larger lateral grain growth, than can be obtained with techniques such as CVD or sputtering. In some embodiments, grains of at least 100 Å wide are grown. Example W ALD deposition conditions that can provide lateral grain growth include 300° C. to 500° C. substrate temperature, or less than 500° C. and 10 torr to 50 torr chamber pressure.

Examples of applications include 3D NAND word line fill and DRAM bWL fill. In these applications, a single template layer of molybdenum (or other template layer) may be used with the remainder of the feature filled with tungsten (or other main conductor). The Mo other template layer may be deposited on layers such as titanium nitride (TiN) or oxides such as silicon oxide (e.g., SiO₂), aluminum oxide (e.g., Al₂O₃), hafnium oxide (e.g., HfO₂), and zirconium oxide (e.g., ZrO₂).

### Experimental

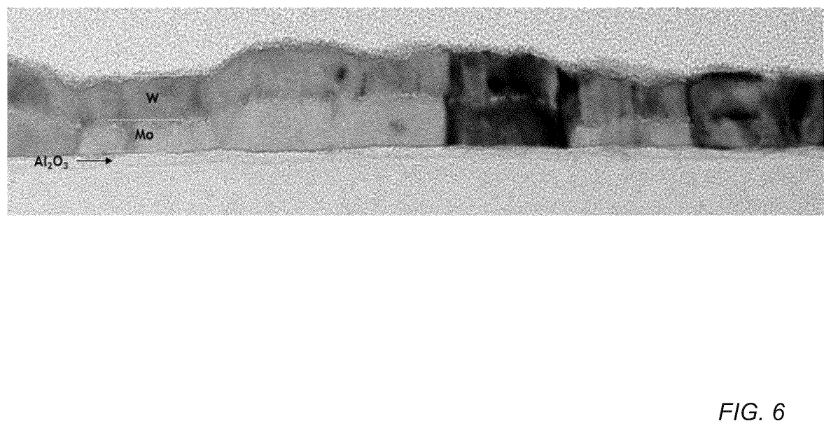

A molybdenum film was grown directly on Al₂O₃, followed by an anneal, and tungsten deposition. FIG. 6 shows an image of the W film on the Mo film. The image shows that the W grains are templating off the Mo grains below.

In some embodiments, a thermal anneal is performed after Mo deposition. This can allow Mo grain growth and lower resistivity. Because the melting point of Mo is lower than that of W, grain growth and the accompanying decrease in resistivity occur at lower temperatures for Mo films. Examples of anneal temperatures range from 700° C. to 1100° C. The anneal may be performed in a furnace or by rapid thermal annealing. According to various embodiments, it may be performed in any appropriate ambient, including a hydrogen (H₂) ambient, a nitrogen (N₂) ambient, or vacuum.

According to various embodiments, the Mo film may or may not be exposed to air between deposition and annealing. If it is exposed to air or other oxidizing environment, a reducing environment may be employed during or before anneal to remove molybdenum dioxide (MoO₂) or molybdenum trioxide (MoO₃) that has formed as a result of the exposure. MoO₃ in particular has a melting point of 795° C. and could melt during anneal if not removed.

Table 1, below, compares two W films (A and B) and two Mo films (C and D)

| | A | B | C | D |
|---|---|---|---|---|
| Resistivity | 20 μΩ-cm at | 28 μΩ-cm at | 25 μΩ-cm at | 17 μΩ-cm at |
| | 20 nm | 20 nm | 10 nm | 10 nm (after 800 C. |
| | | 40 μΩ-cm at | | anneal) |
| | | 10 nm | | |
| Composition | <3E18 at/cm³ F | <5E18 at/cm³ Cl, | 95% Mo + 5% H, | <1% O, |
| | | F below detection | <1E19 at/cm³ Cl | <1E19 at/cm³ Cl |
| | | limit | | |
| Stress | <0.55 Gpa @ | <0.2 Gpa @ | 0.4 GPa @ | 0.6 GPa @ |
| | 20 nm | 20 nm | 70 nm | 30 nm |

Film A is a tungsten film deposited using WF₆. Film B is a tungsten film deposited using WCl₅ and WCl₆. Film C is a molybdenum film deposited using MoCls and film D is a molybdenum film deposited using MoOCl₄. Film D was subject to a post-deposition anneal. Notably, the resistivity is lower for Films C and D than films A and B. Resistivity decreases with thickness, with the 25 μΩ-cm (film C) and 17 μΩ-cm (film D) directly comparable to the 40 μΩ-cm (film A). Film D, deposited with an O-containing precursor, shows low O. The stress of films C and D is comparable to that of films A and B.

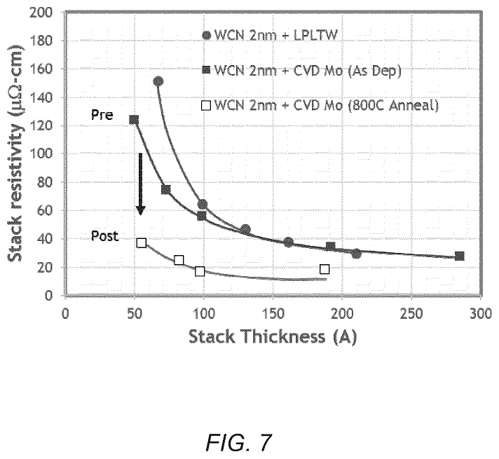

FIG. 7 is a graph showing the reduction in resistivity for Mo films of various thicknesses deposited on WCN after anneal at 800° C. Resistivity of a W film on WCN is also shown for comparison. A significant decrease in resistivity is observed. The decrease in resistivity is due to grain growth. Table 2, below, shows phases and average grain size for Mo grains in as deposited and post-anneal CVD Mo films.

| | | Average Crystallite |
|---|---|---|
| Sample | Phase | Size (nm) |
| CVD Mo/WCN as deposited | Mo - Molybdenum | 14.5 |
| | Cubic | |
| CVD Mo/WCN post-anneal | Mo - Molybdenum | 33.5 |
| | Cubic | |

Furnace anneals of 1 hour and 5 mins at 800° C. in H₂ ambient showed comparable results.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems. The process can be performed on multiple deposition stations in parallel.

In some embodiments, a molybdenum template deposition process is performed at a first station that is one of two, five, or even more deposition stations positioned within a single deposition chamber. In some embodiments, various steps for the process are performed at two different stations of a deposition chamber. For example, the substrate may be exposed to H₂ in a first station using an individual gas supply system that creates a localized atmosphere at the substrate surface, and then the substrate may be transferred to a second station to be exposed to a precursor such as MoOCl₅ to deposit the template layer. In some embodiments, the substrate may then be transferred back to the first station for a second exposure of hydrogen. Then the substrate may be transferred to the second station for exposure to MoOCl₅ (or other tungsten chloride). This may be repeated as necessary to complete Mo template deposition and proceed with tungsten deposition in the same or different station. One or more stations can then be used to perform tungsten deposition as described above.

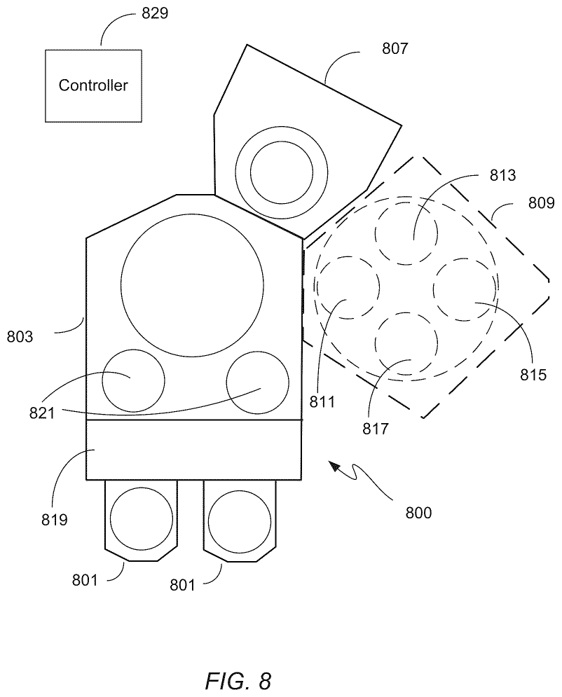

FIG. 8 is a block diagram of a processing system suitable for conducting deposition processes in accordance with embodiments described herein. The system 800 includes a transfer module 803. The transfer module 803 provides a clean, pressurized environment to minimize the risk of contamination of substrates being processed as they are moved between the various reactor modules. Mounted on the transfer module 803 is a multi-station reactor 809 capable of performing nucleation layer deposition, which may be referred to as pulsed nucleation layer (PNL) deposition, as well as ALD and CVD deposition according to embodiments described herein. Chamber 809 may include multiple stations 811, 813, 815, and 817 that may sequentially perform these operations. For example, chamber 809 could be configured such that stations 811 and 813 perform PNL or ALD deposition, and stations 813 and 815 perform CVD. Each deposition station may include a heated wafer pedestal and a showerhead, dispersion plate or other gas inlet.

Also mounted on the transfer module 803 may be one or more single or multi-station modules 807 capable of performing plasma or chemical (non-plasma) pre-cleans. The module may also be used for various other treatments, e.g., reducing agent soaking. The system 800 also includes one or more (in this case two) wafer source modules 801 where wafers are stored before and after processing. An atmospheric robot (not shown) in the atmospheric transfer chamber 819 first removes wafers from the source modules 801 to loadlocks 821. A wafer transfer device (generally a robot arm unit) in the transfer module 1103 moves the wafers from loadlocks 821 to and among the modules mounted on the transfer module 803.

In certain embodiments, a system controller 829 is employed to control process conditions during deposition. The controller will typically include one or more memory devices and one or more processors. The processor may include a CPU or computer, analog and/or digital input/output connections, stepper motor controller boards, etc.

The controller may control all of the activities of the deposition apparatus. The system controller executes system control software including sets of instructions for controlling the timing, mixture of gases, chamber pressure, chamber temperature, wafer temperature, radio frequency (RF) power levels if used, wafer chuck or pedestal position, and other parameters of a particular process. Other computer programs stored on memory devices associated with the controller may be employed in some embodiments.

Typically there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language. Alternatively, the control logic may be hard coded in the controller. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place.

The computer program code for controlling the deposition and other processes in a process sequence can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the deposition processes described herein. Examples of programs or sections of programs for this purpose include substrate positioning code, process gas control code, pressure control code, heater control code, and plasma control code.

In some implementations, a controller 829 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 829, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 829, in some implementations, may be a part of or coupled to a computer that is integrated with, coupled to the system, otherwise networked to the system, or a combination thereof. For example, the controller 829 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 829 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions.

The foregoing describes implementation of embodiments of the disclosure in a single or multi-chamber semiconductor processing tool.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In the description above and in the claims, numerical ranges are inclusive of the end points of the range. For example, “a thickness between 1 and 5 nm” includes 1 nm and 5 nm. Similarly, ranges represented by a dash are inclusive of the end points of the ranges.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
depositing a molybdenum (Mo)-containing layer in a feature on a substrate; and
depositing tungsten (W) on the Mo-containing layer to thereby fill the feature with tungsten.

2. The method of claim 1, further comprising thermally annealing the Mo-containing layer prior to depositing tungsten.

3. The method of claim 1, wherein the Mo-containing layer is a template for W grain growth.

4. The method of claim 1, wherein the Mo-containing layer is elemental Mo having less than 1 (atomic) % impurities.

5. The method of claim 1, wherein the Mo-containing layer is between 1 and 10 nm thick.

6. The method of claim 1, wherein the Mo-containing layer overlies a dielectric layer.

7. The method of claim 1, wherein the Mo-containing layer is free of fluorine impurities.

8. The method of claim 1, further comprising depositing the Mo-containing layer.

9. The method of claim 8, wherein the Mo-containing layer is deposited from one or more molybdenum chloride precursors.

10. The method of claim 9, wherein the one or more molybdenum chloride precursors are selected from: molybdenum pentachloride (MoCl₅), molybdenum dichloride dioxide (MoO₂Cl₂), and molybdenum tetrachloride oxide (MoOCl₄).
